(19) United States
(12) Patent Application Publication
(10) Pub. No.: US 2025/0300076 A1
(43) Pub. Date: Sep. 25, 2025

(54) STACKED COMPLIMENTARY METAL-OXIDE SEMICONDUCTOR STRUCTURE

(71) Applicant: International Business Machines Corporation, Armonk, NY (US)

(72) Inventors: Ruilong Xie, Niskayuna, NY (US); Kisik Choi, Watervliet, NY (US); Biswanath Senapati, Mechanicville, NY (US); Shay Reboh, Guilderland, NY (US); James P Mazza, Saratoga Springs, NY (US)

(21) Appl. No.: 18/611,804

(22) Filed: Mar. 21, 2024

(51) Int. Cl. H01L 23/528; H01L 23/522; H01L 27/092; H01L 29/06; H01L 29/423; H01L 29/775; H01L 29/786

(52) U.S. Cl. CPC H01L 23/5283; H01L 23/5226; H10D 30/43; H10D 30/6735; H10D 30/6757; H10D 62/121; H10D 84/856

(57) ABSTRACT

A microelectronic structure that includes a stack FET array, wherein the stack FET array includes a frontside cell and a backside cell, wherein the frontside cell and the backside cell are vertically aligned, wherein the frontside cell includes a first frontside transistor and a second frontside transistor, wherein the first frontside transistor is located horizontally adjacent to the second frontside transistor. A connecting via extending from a frontside of the stacked FET array to a backside of the stacked FET array, wherein the connecting via is located at the boundary of the stacked FET array.

### BACKGROUND

The present invention generally relates to the field of microelectronics, and more particularly to forming cells in a stack FET.

A complimentary metal-oxide semiconductor (CMOS) may be frequently used in many of today's integrated circuits (ICs). CMOS transistors may be based on metal-oxide semiconductor field-effect transistor technology (MOSFET) technology, where MOSFETs may serve as switches or amplifiers that may control the amount of electricity flowing between source and drain terminals based on an amount of applied voltage. However, stack FET scaling may be challenging because of the need for top to bottom communication.

### BRIEF SUMMARY

Additional aspects and/or advantages will be set forth in part in the description which follows and, in part, will be apparent from the description, or may be learned by practice of the invention.

A microelectronic structure that includes a stack FET array, wherein the stack FET array includes a frontside cell and a backside cell, wherein the frontside cell and the backside cell are vertically aligned, wherein the frontside cell includes a first frontside transistor and a second frontside transistor, wherein the first frontside transistor is located horizontally adjacent to the second frontside transistor. A connecting via extending from a frontside of the stacked FET array to a backside of the stacked FET array, wherein the connecting via is located at the boundary of the stacked FET array.

A microelectronic structure that includes a stack FET array, wherein the stack FET array includes a plurality of stacked cells, wherein each of the plurality of stacked cells includes a frontside cell and a backside cell, wherein each of the frontside cells includes a first frontside transistor and a second frontside transistor, wherein the first frontside transistor is located horizontally adjacent to the second frontside transistor. A connecting via extending from a frontside of the stacked FET array to a backside of the stacked FET array, wherein the connecting via is located at a boundary of the stacked FET array.

A microelectronic structure that includes a first stack FET array, wherein the first stack FET array includes a plurality of first stacked cells, wherein each of the plurality of first stacked cells includes a frontside cell and a backside cell, wherein each of the frontside cells includes a first frontside transistor and a second frontside transistor, wherein the first frontside transistor is located horizontally adjacent to the second frontside transistor. A second stack FET array, wherein the second stack FET array includes a plurality of second stacked cells, wherein each of the plurality of second stacked cells includes a frontside cell and a backside cell, wherein each of the backside cells includes a first backside transistor and a second backside transistor, wherein the first backside transistor is located horizontally adjacent to the second backside transistor. A connecting via extending from a frontside of the first stack FET array and a frontside of the second stack FET array to a backside of the first stack FET array and a backside of the second stack FET array, wherein the connecting via is located at an end boundary between the first stack FET array and a beginning boundary of the second stack FET array. A plurality of frontside metal tracks, wherein two frontside metal tracks of the plurality of frontside metal tracks are associated with each of the frontside transistors. A plurality of backside metal tracks, wherein two backside metal tracks of the plurality of backside metal tracks are associated with each of the backside transistors.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a top-down view of the nanosheet transistor array, in accordance with the embodiment of the present invention.

FIG. 2 illustrates a cross section Y of the source/drain region of the nanosheet transistor array after the initial processing of a plurality of stacked FET, in accordance with the embodiment of the present invention.

FIG. 3 illustrates a cross section Y of the source/drain region of the nanosheet transistor array after forming of the middle-of-line (MOL) contacts, back-end-of-line (BEOL), and a carrier wafer, in accordance with the embodiment of the present invention.

FIG. 4 illustrates a cross section Y of the source/drain region of the nanosheet transistor array after the flipping of the device over for backside processing, in accordance with the embodiment of the present invention.

FIG. 5 illustrates a cross section Y of the source/drain region of the nanosheet transistor array after the removal of the first substrate, in accordance with the embodiment of the present invention.

FIG. 6 illustrates a cross section Y of the source/drain region of the nanosheet transistor array after the removal of the etch stop and the second substrate, in accordance with the embodiment of the present invention.

FIG. 7 illustrates a cross section Y of the source/drain region of the nanosheet transistor array after backside CM patterning, in accordance with the embodiment of the present invention.

FIG. 8 illustrates a cross section Y of the source/drain region of the nanosheet transistor array after the removal of the placeholder, in accordance with the embodiment of the present invention.

FIG. 9 illustrates a cross section Y of the source/drain region of the nanosheet transistor array after backside contract metallization, in accordance with the embodiment of the present invention.

FIG. 10 illustrates a cross section Y of the source/drain region of the nanosheet transistor array after forming the backside interconnect including cell array division lines, in accordance with the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout.

A vertical stack FET cell includes one upper transistor and one lower transistor with opposite polarity (e.g. one is an NFET, and the other is a PFET). Stack FET scaling may be challenging because of the need wiring the multiple components imposes spaces restrictions. As size of the stack FET decreases it is increasingly difficult to utilize a two track design.

In the present invention is directed towards horizontal stacked FET cells. Each of the stacked FET cells includes a first transistor and a horizontally adjacent second transistor with opposite polarity (e.g. one is an NFET, and the other is a PFET). Each of the stacked FET cells includes four metal tracks, the first transistor and the horizontally adjacent second transistor each include two metal tracks. Additionally, the present invention utilizes skip vias between the horizontal stacked FET arrays between varying numbers of cell boundaries depending on circuit design providing improved stack FET scaling.

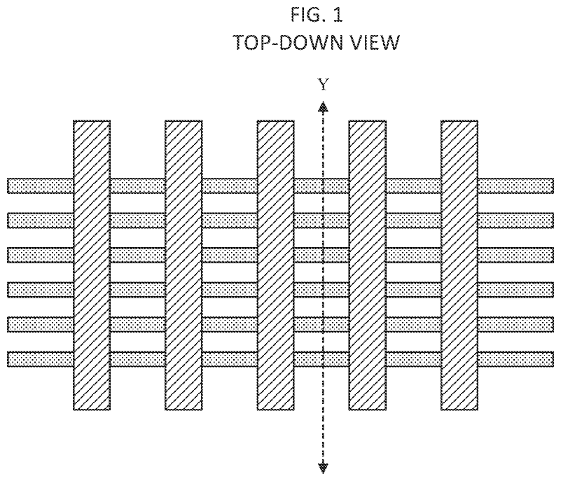

FIG. 1 illustrates a top-down view of multiple devices, in accordance with the embodiment of the present invention. The cross-section X extends horizontally through nanosheet transistors. Cross section Y is perpendicular to cross section X, where cross section Y is through a source/drain region that spans across multiple adjacent nanosheet transistors. Cross-section X is perpendicular to the gate direction and cross-section Y is parallel to the gate direction.

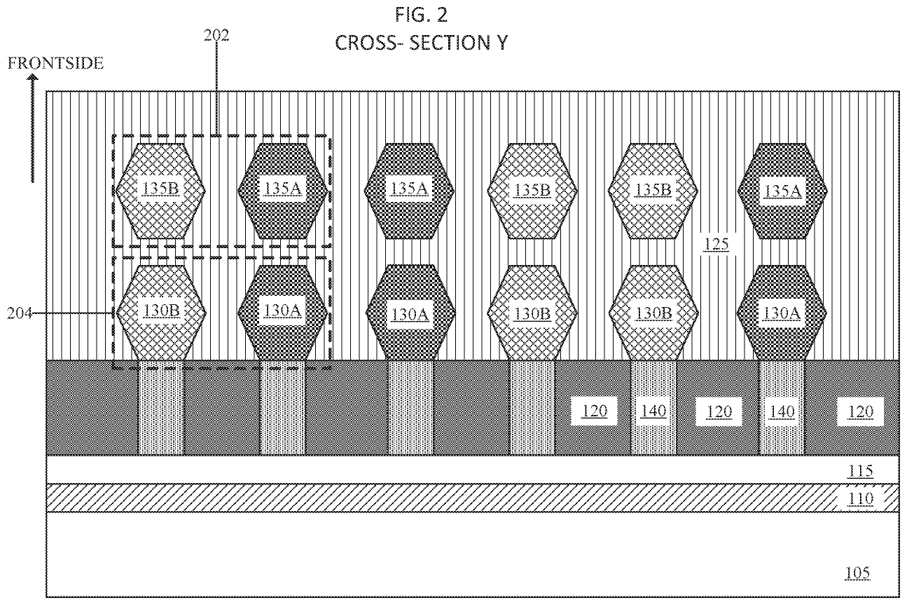

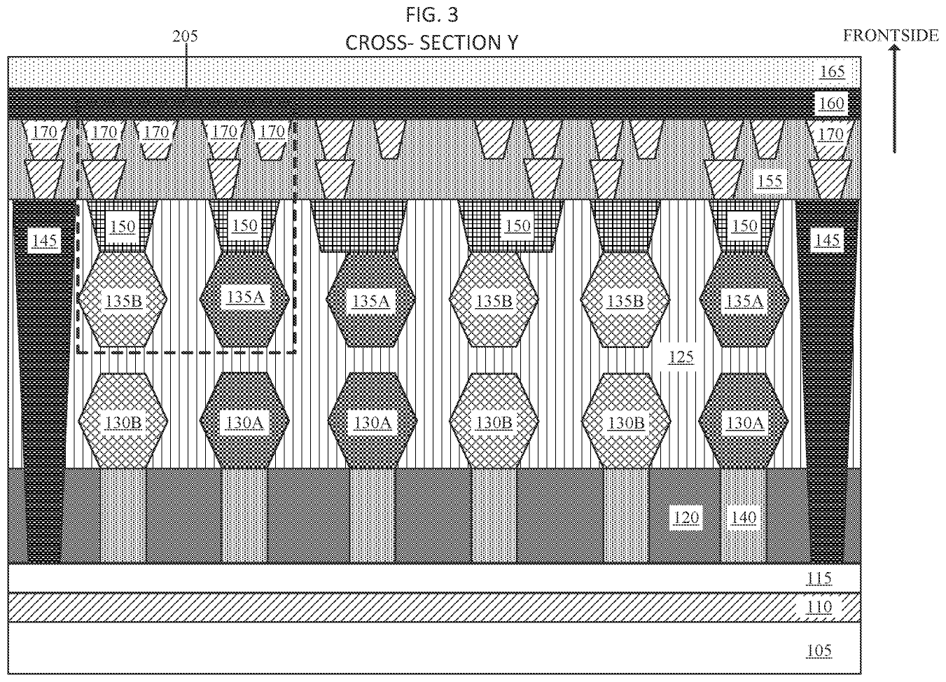

Referring now to FIGS. 2 and 3, a structure is shown during an intermediate step of a method of fabricating after the formation of the source/drain regions.

FIG. 3 illustrates the processing stage after the completion of the frontside processing of the nanosheet transistors.

FIG. 2 illustrates the nanosheet transistor array that includes a first substrate 105, an etch stop 110, a second substrate 115, a shallow trench isolation layer 120, a frontside interlayer dielectric layer 125, an array of stacked FETs and placeholder 140. Placeholder 140 is located beneath parts of the stacked FET array, and the shallow trench isolation layer 120 is located between the placeholders 140.

The first substrate 105 and the second substrate 115 can be, for example, a material including, but not necessarily limited to, silicon (Si), silicon germanium (SiGe), Si:C (carbon doped silicon), carbon doped silicon germanium (SiGe:C), III-V, II-V compound semiconductor or another like semiconductor. In addition, multiple layers of the semiconductor materials can be used as the semiconductor material of the first substrate 105 and the second substrate 115. In some embodiments, the first substrate 105 and the second substrate 115 includes both semiconductor materials and dielectric materials. The semiconductor first substrate 105 and the second substrate 115 may also comprise an organic semiconductor or a layered semiconductor such as, for example, Si/SiGe, a silicon-on-insulator or a SiGe-on-insulator. A portion or the entire semiconductor first substrate 105 and the second substrate 115 may also be comprised of an amorphous, polycrystalline, or monocrystalline. The semiconductor first substrate 105 and the second substrate 115 may be doped, undoped or contain doped regions and undoped regions therein.

Horizontal stack FET array includes at a minimum at least one upper cell (or frontside cell) and at least one lower cell (or backside cell). The at least one frontside cell, as emphasized by dashed box 202, includes a first frontside transistor (where the figures illustrate one source/drain 135A of the first frontside transistor) and a second frontside transistor (where the figures illustrate one source/drain 135B of the second frontside transistor). The at least one backside cell, as emphasized by dashed box 204, includes a first backside transistor (where the figures illustrate one source/drain 130A of the first backside transistor) and a second backside transistor (where the figures illustrate one source/drain 130B of the second backside transistor). At least one backside cell (or lower cell) is being referred to as the backside cell because the backside transistors are connected to the backside interconnect, which will be described in further detail below. The first frontside transistor and second frontside transistor have opposite polarity (e.g. one is an NFET, and the other is a PFET), and the first backside transistor and second backside transistor have opposite polarity (e.g. one is an NFET, and the other is a PFET).

The first frontside source/drain 135A (e.g., the frontside source/drain of the first frontside transistor), the second frontside source/drain 135B (e.g., the second frontside source/drain of the second frontside transistor), a first backside source/drain 130A (e.g., the first backside source/drain of the first backside transistor), and the second source/drain 130B (e.g., the second backside source/drain of the second backside transistor) can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

FIG. 3 illustrates the nanosheet transistor arrays that includes connecting via 145, frontside contacts 150, frontside layer 155, back-end-of-line (BEOL) layer 160, carrier wafer 165, and a plurality of metal line(s) 170 or metal track(s) 170. A lithography layer (not shown) is formed on the frontside interlayer dielectric layer 125. The lithography layer and the frontside interlayer dielectric layer 125 are patterned to form a plurality of trenches (not shown). The frontside contacts 150 and the connecting vias 145 are formed by filling these trenches with a conductive metal. The frontside layer 155 is formed on the frontside interlayer dielectric layer 125, frontside contacts 150, and connecting via(s) 145. The frontside layer 155 can be comprised of, for example, the same material as the interlayer dielectric layer 125, a different dielectric material, or any other suitable material. A lithography layer (not shown) is formed on the frontside layer 155. The lithography layer and the frontside layer 155 are patterned to form a plurality of trenches (not shown) within the frontside later 155. The plurality of metal line(s) 170 or metal track(s) 170 and connecting via(s) 145 are formed by filling these trenches with a conductive metal. The plurality of metal line(s) 170 or metal track(s) 170 may be utilized for a plurality of purposes, such as, but not limited to, power, signal communication, ground, clock, amongst other purposes. Each cell, as emphasized by dashed box 205, includes four metal track(s) 170, two metal track(s) 170 are located above a first frontside source/drain 135A (e.g., the first frontside source/drain of the first frontside transistor) and two metal track(s) 170 are located above a second frontside source/drain 135B (e.g., the second frontside source/drain of the second frontside transistor). At least one of the two metal track(s) 170 located above the first frontside source/drain 135A (e.g., the first frontside source/drain of the first frontside transistor)) are connected to the first frontside source/drain 135A (e.g., the first frontside source/drain of the first frontside transistor) via the frontside contacts 150, as illustrated. At least one of the two metal track(s) 170 located above the second frontside source/drain 135B (e.g., the second frontside source/drain of the second frontside transistor) are connected to the second frontside source/drain 135B (e.g., the second frontside source/drain of the second frontside transistor) via the frontside contacts 150, as illustrated. The metal line(s) 170 or metal track(s) 170 are also connected with the frontside of the connecting via(s) 145.

The BEOL layer 160 is formed on top of the frontside of the frontside layer 155 and the frontside of the plurality of metal line(s) 170 or metal track(s) 170. The carrier wafer is formed on top of the frontside of the BEOL layer 160. The carrier wafer 165 allows for the nanosheet transistor array to be flipped over for backside processing.

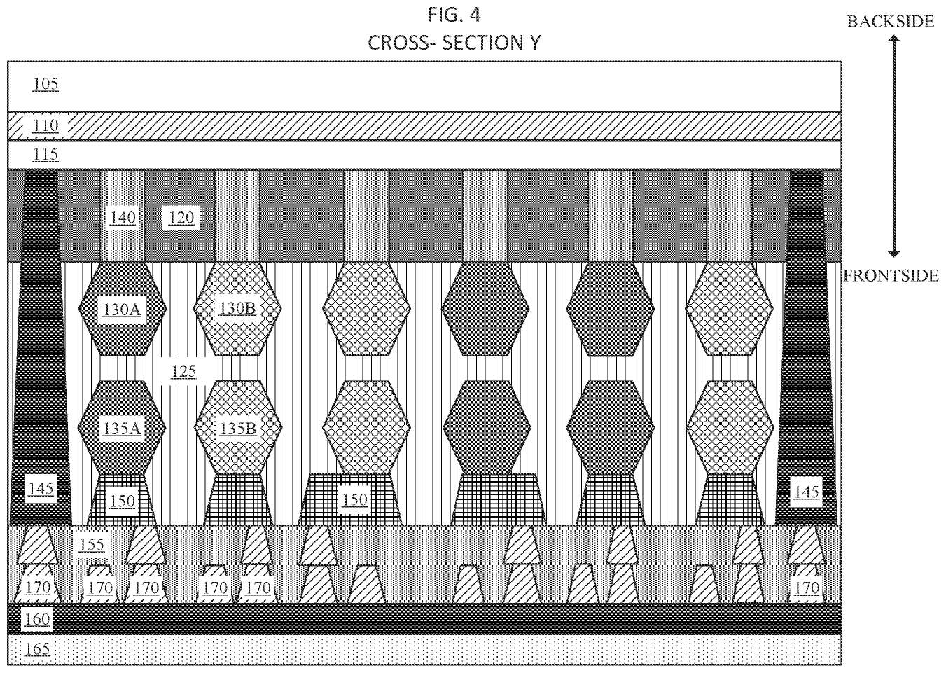

FIGS. 4-10 illustrate the processing stage after flipping the nanosheet transistor array over for backside processing. Carrier wafer 165 allows for the nanosheet transistor array (logic device, or logic device with a passive device) to be flipped over for backside processing, i.e., flipping over the nanosheet transistor exposes the backside region of the device. FIGS. 2 and 3 illustrated the frontside processing of the nanosheet transistor array and FIGS. 4-10 illustrate the backside processing of the nanosheet transistor array.

FIGS. 4, 5, and 6 illustrate the processing stage after the flipping of the nanosheet transistor array for backside processing, removal of the first substrate 105, the etch stop 110, and the second substrate 115.

FIG. 4 illustrates the nanosheet transistor array after it has been flipped over, using the carrier wafer 165, for backside processing. The nanosheet transistor array was flipped over, using the carrier wafer 165, exposing the first substrate 105 to the processing tools utilized for processing.

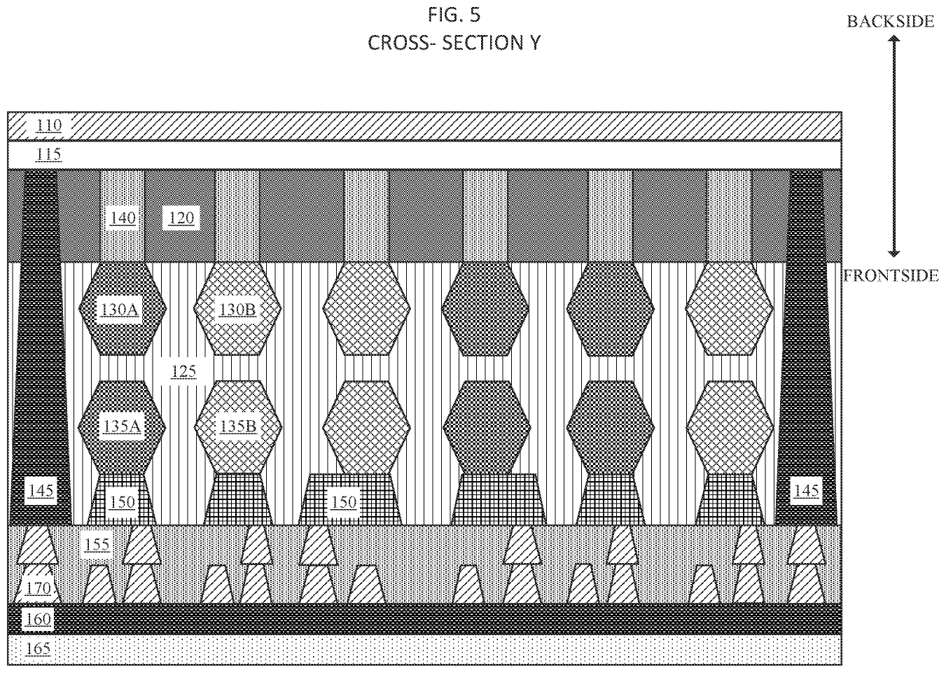

FIG. 5 illustrates the nanosheet transistor array after the removal of the first substrate 105. First substrate 105 was removed by wafer grinding process, chemical mechanical planarization (CMP), dry etch and selective wet etch or other suitable etching means to expose the etch stop layer 110.

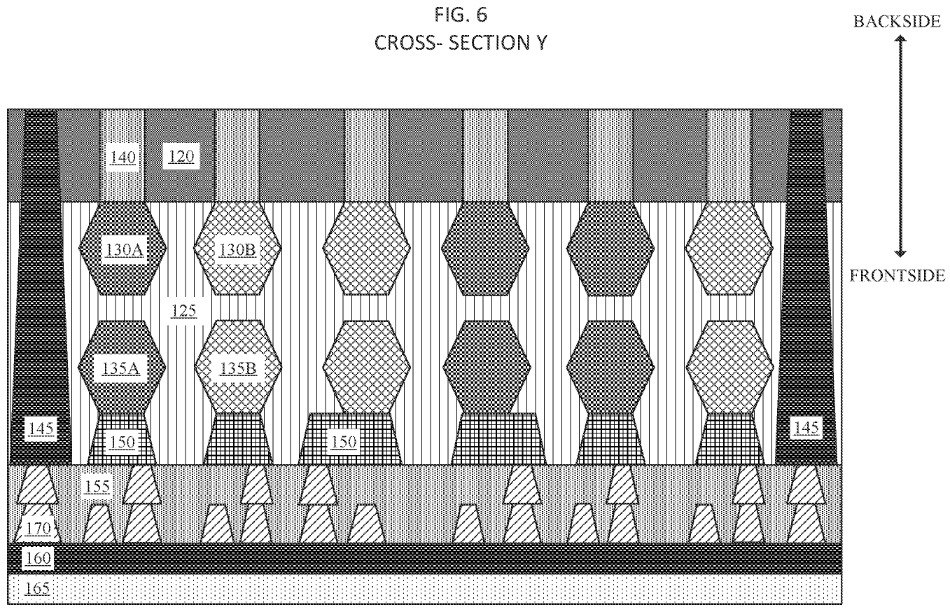

FIG. 6 illustrates the nanosheet transistor array after the removal of the etch stop 110 and the second substrate 115 to expose a backside surface of the placeholder(s) 140 and shallow trench isolation layer 120. The etch stop 110 was removed by selective wet etch or other suitable etching means to expose the second substrate 115. The second substrate 115 was removed by selective wet etch or other suitable etching means to expose shallow trench isolation layer 120 and placeholder(s) 140 for further backside processing.

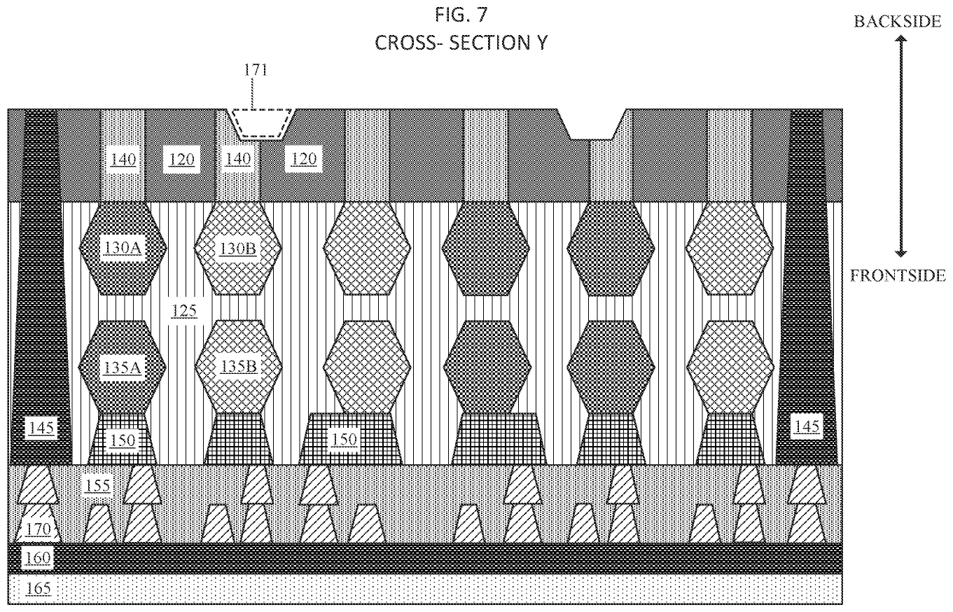

FIG. 7 illustrates the nanosheet transistor array after etching. A lithography layer (not shown) is formed on top of the frontside of the connecting via(s) 145, the frontside of the placeholder(s) 140, and the frontside of the shallow trench isolation layer 120. The placeholder(s) 140 and the shallow trench isolation layer 120 were etched using, Reactive-ion etching (REI), or other suitable etching means to begin the formation of the lateral backside contact trench 171. The lateral backside contact trench 171 are located at the boundary between the placeholder(s) 140 and the shallow trench isolation layer 120, as illustrated. The lithography layer is removed to expose the frontside surfaces of the connecting via(s) 145, placeholder(s) 140, and the shallow trench isolation layer 120 surfaces.

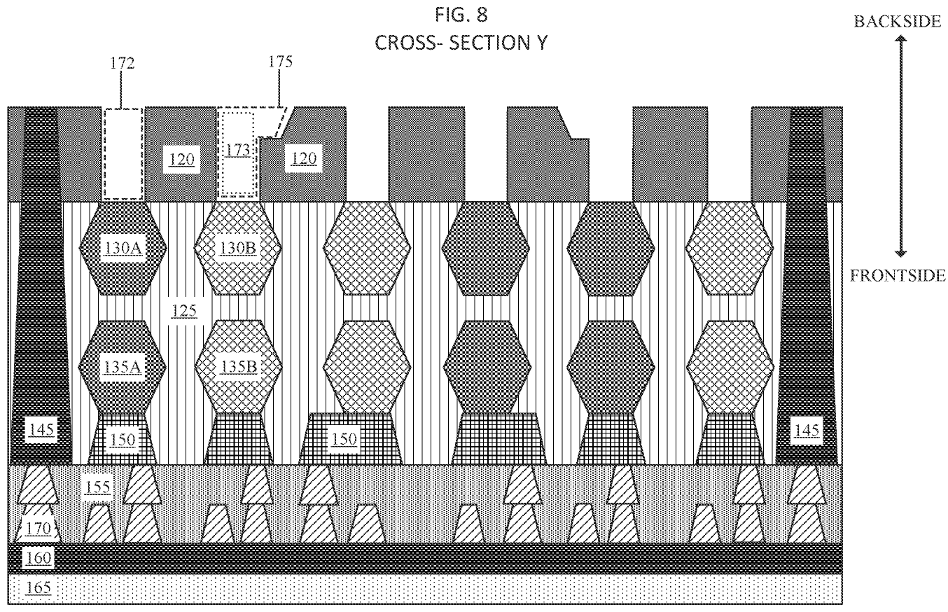

FIG. 8 illustrates the nanosheet transistor array after placeholder(s) 140 removal. The placeholder(s) 140 was etched using a suitable dry or wet etch to selectively target the placeholder(s) 140, or other suitable means to form the backside contact trenches 172 and 175. A first backside contact trench 172 has a mostly vertical profile as illustrated in FIG. 8. A second backside trench 175 has an inverted L-shaped profile because lateral backside trench 171 of FIG. 7 is combined with a vertical trench 173 in forming the second backside contact trench 175. A second backside contact trench 175 in which the placeholder was removed and there was lateral etching is emphasized by dashed box 175. The placeholder(s) 140 and the shallow trench isolation layer 120 are laterally etched to widen/increase the width of the backside contact trench which improves/makes easier backside wiring.

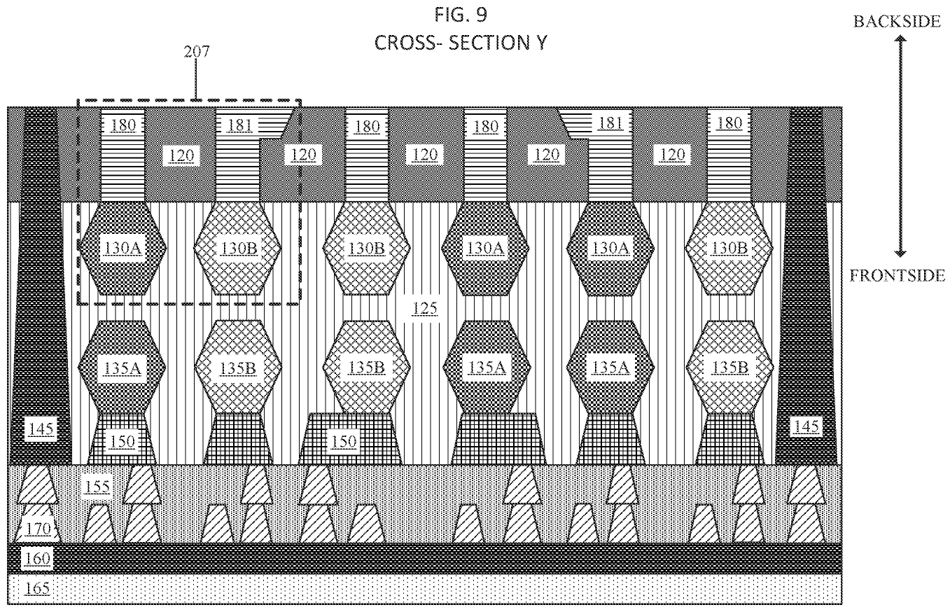

FIG. 9 illustrates the nanosheet transistor array after backside contact metallization. The first backside contact(s) 180 corresponds to the first backside contact trench 172 of FIG. 8 after it is filled with a conductive material. The second backside contact(s) 181 corresponds to the second backside contact trench 175 of FIG. 8 after it is filled with a conductive material. The conductive material is utilized to form the first backside contact(s) 180 with the first backside source/drain 130A (e.g., the first backside source/drain of the first backside transistor) and the conductive material is utilized to form the second backside contact(s) 181 with the second source/drain 130B (e.g., the second backside source/drain of the second backside transistor), of the backside cells of the horizontal stack FET array as emphasized by dashed box 207.

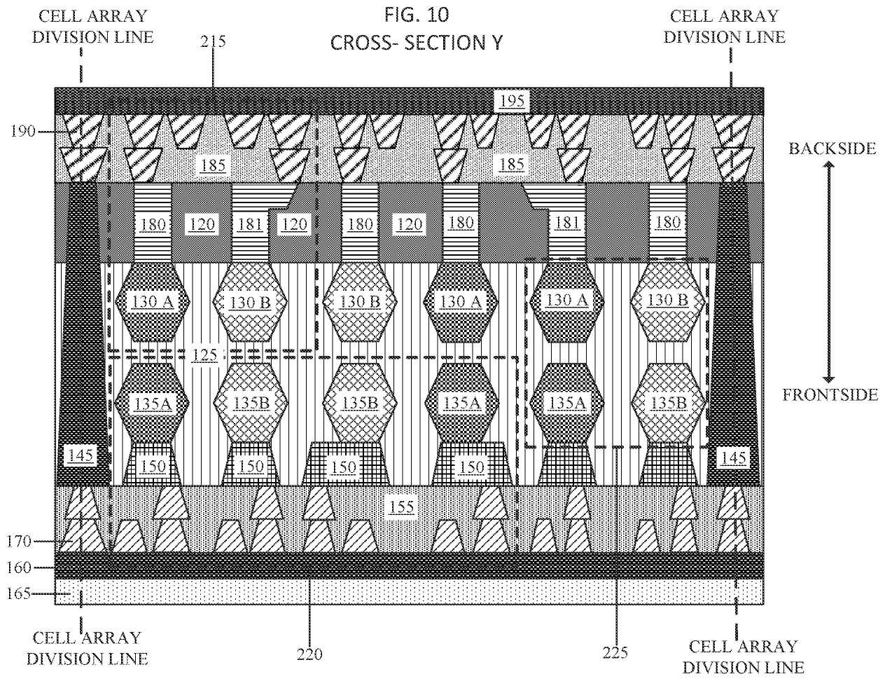

FIG. 10 illustrates the nanosheet transistor array after forming the backside interconnect. FIG. 10 illustrates the nanosheet transistor arrays that includes, a backside interlayer dielectric layer 185, backside back-end-of-line (BBEOL) layer 195, and a plurality of backside metal line(s) 190 or backside metal track(s) 190. FIG. 10 additionally illustrates the nanosheet transistor array after forming the backside interconnect including two cell array division lines through depicting the boundaries of the horizontal stack FET array. As will be explained in greater detail below, although six cells are depicted, three frontside cells and three backside cells, the invention may utilize a hybrid approach such that the contact wires may be present between varying numbers of cell boundaries of the horizontal stack FET array. The backside interlayer dielectric layer 185 is formed on the backside of the shallow trench isolation layer 120, the first backside contact(s) 180, the second backside contact(s) 181, and connecting via(s) 145. The backside interlayer dielectric layer 185 can be comprised of, for example, the same material as interlayer dielectric layer 125, frontside layer 155, a different dielectric material, or any other suitable material. A lithography layer (not shown) is formed on the backside interlayer dielectric layer 185. The lithography layer and the backside interlayer dielectric layer 185 are patterned to form a plurality of trenches (not shown) within the backside interlayer dielectric layer 185. The plurality of backside metal line(s) 190 or backside metal track(s) 190 are formed by filling these trenches with a conductive metal. The plurality of backside metal line(s) 190 or backside metal track(s) 190 may be utilized for a plurality of purposes, such as, but not limited to, power, signal communication, ground, clock, amongst other purposes. The BBEOL layer 195 is formed on top of the backside of the backside interlayer dielectric layer 185 and on top of the backside of the backside metal line(s) 190 or backside metal track(s) 190.

Each backside cell, as emphasized by dashed box 215, includes four backside metal track(s) 190, two backside metal track(s) 190 are located above a first backside source/drain 130A (e.g., the first backside source/drain of the first backside transistor) and two backside metal track(s) 190 are located above a second source/drain 130B (e.g., the second backside source/drain of the second backside transistor). At least one of the backside two backside metal track(s) 190 located above the first backside source/drain 130A (e.g., the first backside source/drain of the first backside transistor) are connected to the first backside source/drain 130A (e.g., the first backside source/drain of the first backside transistor) via either the first backside contact(s) 180 or the second backside contact(s) 181, as illustrated. At least one of the two backside metal track(s) 190 located above the second source/drain 130B (e.g., the second backside source/drain of the second backside transistor) are connected to the second source/drain 130B (e.g., the second backside source/drain of the second backside transistor) via either the first backside contact(s) 180 or the second backside contact(s) 181, as illustrated. The backside metal line(s) 190 or backside metal track(s) 190 are also connected with the backside of the connecting via(s) 145. Dashed box 220 emphasizes two frontside cells, wherein each of the two frontside cells includes a first frontside source/drain 135A (e.g., the first frontside source/drain of the first frontside transistor) and a second frontside source/drain 135B (e.g., the second frontside source/drain of the second frontside transistor). Dashed box 220 additionally includes four frontside contact(s) 150 and eight metal line(s) 170 or metal track(s) 170. Two of the metal line(s) 170 or two metal track(s) 170 are located to the first frontside source/drain 135A (e.g., the first frontside source/drain of the first frontside transistor) and the second frontside source/drain 135B (e.g., the second frontside source/drain of the second frontside transistor) of each of the frontside cells. One of the two metal line(s) or two metal track(s) 170 are connected to each first frontside source/drain 135A (e.g., the first frontside source/drain of the first frontside transistor) and the second frontside source/drain 135B (e.g., the second frontside source/drain of the second frontside transistor) of each of the frontside cells via one of the four frontside contact(s) 150, as illustrated. Dashed box 225 emphasizes a horizontally stacked FET, each horizontally stacked FET includes at least one backside cell and at least one frontside cell. Each frontside cell includes a first frontside source/drain 135A (e.g., the first frontside source/drain of the first frontside transistor) and a second frontside source/drain 135B (e.g., the second frontside source/drain of the second frontside transistor), the first frontside source/drain 135A (e.g., the first frontside source/drain of the first frontside transistor) is located horizontally adjacent to the second frontside source/drain 135B (e.g., the second frontside source/drain of the second frontside transistor). Each backside cell includes a first backside source/drain 130A (e.g., the first backside source/drain of the first backside transistor) and a second source/drain 130B (e.g., the second backside source/drain of the second backside transistor), the first backside source/drain 130A (e.g., the first backside source/drain of the first backside transistor) is located horizontally adjacent to the second source/drain 130B (e.g., the second backside source/drain of the second backside transistor).

For illustrative purposes, the Figures of the present invention illustrate one stack FET array that includes three stacked FET cells where each of the stacked cells includes a frontside cell and a backside cell. Each of the depicted frontside cells includes a horizontally aligned adjacent first frontside source/drain 135A (e.g., the first frontside source/drain of the first frontside transistor) and a second frontside source/drain 135B (e.g., the second frontside source/drain of the second frontside transistor). Each of the depicted backside cells includes a horizontally aligned adjacent first backside source/drain 130A (e.g., the first backside source/drain of the first backside transistor) and a second source/drain 130B (e.g., the second backside source/drain of the second backside transistor). The figures include two connecting via(s) 145 where each of the connecting via(s) 145 are located at the cell array division line/array edge/array end/array boundary.

While the figures only illustrate one stacked array that includes three stack cells this is not meant to be seen as limiting to the present invention. The stack array can be comprised of one stack cell or a plurality of stacked cells. Furthermore, the stacked array could be comprised of a plurality of stacked arrays, where each of the plurality of stacked arrays could include the same number of stacked cells, fewer stack cells, more stacked cells than what is illustrated by the Figures or from each other. A connecting via 175 is located between each of the plurality of stacked arrays.

A microelectronic structure that includes a stack FET array, the stack FET array includes a frontside cell and a backside cell, wherein the frontside cell and the backside cell are vertically aligned, the frontside cell includes a first frontside source/drain 135A (e.g., the first frontside source/drain of the first frontside transistor) and a second frontside source/drain 135B (e.g., the second frontside source/drain of the second frontside transistor), the first frontside source/drain 135A (e.g., the first frontside source/drain of the first frontside transistor) is located horizontally adjacent to the second frontside source/drain 135B (e.g., the second frontside source/drain of the second frontside transistor). A connecting via 145 extending from a frontside of the stacked FET array to a backside of the stacked FET array, the connecting via 145 is located at the boundary of the stacked FET array.

A plurality of metal tracks 170 are associated with the frontside cell. The plurality of metal tracks 170 includes four metal tracks associated with the frontside cell. A first group of two metal tracks from the plurality of metal tracks 170 are associated with the first frontside source/drain 135A (e.g., the first frontside source/drain of the first frontside transistor). A second group of two metal tracks from the plurality of metal tracks 170 are associated with the second frontside source/drain 135B (e.g., the second frontside source/drain of the second frontside transistor). A first metal track of the plurality of metal tracks 170 are associated with a backside of the connecting via(s) 145. A second metal track of the plurality of metal tracks 170 are associated with a frontside of the connecting via(s) 145.

The backside cell includes a first backside source/drain 130A (e.g., the first backside source/drain of the first backside transistor) and a second source/drain 130B (e.g., the second backside source/drain of the second backside transistor). The first backside source/drain 130A (e.g., the first backside source/drain of the first backside transistor) is located horizontally adjacent to the second source/drain 130B (e.g., the second backside source/drain of the second backside transistor). A plurality of backside metal tracks 190 are associated with the backside cell. The plurality of backside metal tracks 190 includes four backside metal tracks associated with the backside cell. A first group of two backside metal tracks from the plurality of backside metal tracks 190 are associated with the first backside source/drain 130A (e.g., the first backside source/drain of the first backside transistor). A second group of two backside metal tracks from the plurality of backside metal tracks 190 are associated with the second source/drain 130B (e.g., the second backside source/drain of the second backside transistor).

A microelectronic structure that includes a stack FET array, wherein the stack FET array includes a plurality of stacked cells, each of the stacked cells includes a frontside cell and a backside cell, each of the frontside cells includes a first frontside source/drain 135A (e.g., the first frontside source/drain of the first frontside transistor) and second frontside source/drain 135B (e.g., the second frontside source/drain of the second frontside transistor), wherein the first frontside source/drain 135A (e.g., the first frontside source/drain of the first frontside transistor) is located horizontally adjacent to the second frontside source/drain 135B (e.g., the second frontside source/drain of the second frontside transistor). A connecting via 145 extending from a frontside of the stacked FET array to a backside of the stacked FET array, wherein the connecting via 145 is located at a boundary of the stacked FET array.

Each of the backside cells include first backside source/drain 130A (e.g., the first backside source/drain of the first backside transistor) and a second source/drain 130B (e.g., the second backside source/drain of the second backside transistor), the first backside source/drain 130A (e.g., the first backside source/drain of the first backside transistor) being located horizontally adjacent to the second source/drain 130B (e.g., the second backside source/drain of the second backside transistor).

The stack FET array includes at least three stacked cells.

The stack FET array includes at least four stacked cells.

A plurality of frontside metal tracks 170, including two frontside metal tracks of the plurality of frontside metal tracks 170 that are associated with both the first frontside source/drain 135A (e.g., the first frontside source/drain of the first frontside transistor) and the second frontside source/drain 135B (e.g., the second frontside source/drain of the second frontside transistor) for each of the stacked cells.

A plurality of backside metal tracks 190, including two backside metal tracks of the plurality of backside metal tracks 190 that are associated with both first backside source/drain 130A (e.g., the first backside source/drain of the first backside transistor) and the second source/drain 130B (e.g., the second backside source/drain of the second backside transistor) for each of the stacked cells.

A microelectronic structure that includes a first stack FET array, the first stack FET array includes a plurality of first stacked cells, each of the plurality of first stacked cells includes a frontside cell and a backside cell. Each of the frontside cells includes a first frontside source/drain 135A (e.g., the first frontside source/drain of the first frontside transistor) and a second frontside source/drain 135B (e.g., the second frontside source/drain of the second frontside transistor), the first frontside source/drain 135A (e.g., the first frontside source/drain of the first frontside transistor) is located horizontally adjacent to the second frontside source/drain 135B (e.g., the second frontside source/drain of the second frontside transistor). A second stack FET array, the second stack FET array includes a plurality of second stacked cells, each of the plurality of second stacked cells includes a frontside cell and a backside cell. Each of the backside cells includes a first backside source/drain 130A (e.g., the first backside source/drain of the first backside transistor) and a second source/drain 130B (e.g., the second backside source/drain of the second backside transistor), the first backside source/drain 130A (e.g., the first backside source/drain of the first backside transistor) is located horizontally adjacent to the second source/drain 130B (e.g., the second backside source/drain of the second backside transistor). A connecting via 145 extending from a frontside of the first stack FET array and a frontside of the second stack FET array to a backside of the first stack FET array and a backside of the second stack FET array. The connecting via 145 is located at an end boundary between the first stack FET array and a beginning boundary of the second stack FET array. A plurality of frontside metal tracks 170, two of the frontside metal tracks of the plurality of frontside metal tracks 170 are associated with each of the frontside transistors 135A/135B. A plurality of backside metal tracks 190, wherein two backside metal tracks of the plurality of backside metal tracks 190 are associated with each of the backside transistors 130A/130B.

The first stack FET array including a first number of cells. The first number of cells of the first stack FET array being the same, less, or greater than a second number of cells of the second stack FET array.

A third stack FET array, the third stack FET array includes a plurality of third stacked cells, each of the plurality of the third stacked cells includes a frontside cell and a backside cell. Each of the frontside cells includes a first frontside source/drain 135A (e.g., the first frontside source/drain of the first frontside transistor) and a second frontside source/drain 135B (e.g., the second frontside source/drain of the second frontside transistor), first frontside source/drain 135A (e.g., the first frontside source/drain of the first frontside transistor) is located horizontally adjacent to the second frontside source/drain 135B (e.g., the second frontside source/drain of the second frontside transistor). Each of the backside cells includes a first backside source/drain 130A (e.g., the first backside source/drain of the first backside transistor) and a second source/drain 130B (e.g., the second backside source/drain of the second backside transistor), the first backside source/drain 130A (e.g., the first backside source/drain of the first backside transistor) is located horizontally adjacent to the second source/drain 130B (e.g., the second backside source/drain of the second backside transistor). A second connecting via 145 extending from a frontside of the second stack FET array and a frontside of the third stack FET array to a backside of the of the second stack FET array and a backside of the third stack FET array. The second connecting via 145 is located at an end boundary between the second stack FET array and a beginning boundary of the third stack FET array.

The third stack FET array including a third number of cells. The third number of cells being the same, less, or greater than a first number of cells of the first stack FET array.

The third stack FET array including a third number of cells. The third number of cells being the same, less, or greater than a second number of cells of the second stack FET array.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A microelectronic structure comprising:
a stack FET array, wherein the stack FET array includes a frontside cell and a backside cell, wherein the frontside cell and the backside cell are vertically aligned, wherein the frontside cell includes a first frontside transistor and a second frontside transistor, wherein the first frontside transistor is located horizontally adjacent to the second frontside transistor; and
a connecting via extending from a frontside of the stacked FET array to a backside of the stacked FET array, wherein the connecting via is located at the boundary of the stacked FET array.

2. The microelectronic structure of claim 1, further comprising:
a plurality of metal tracks are associated with the frontside cell.

3. The microelectronic structure of claim 2, wherein the plurality of metal tracks includes four metal tracks associated with the frontside cell.

4. The microelectronic structure of claim 3, wherein a first group of two metal tracks of the four metal tracks are associated with the first frontside transistor and a second group of two metal tracks of the four metal tracks are associated with the second frontside transistor.

5. The microelectronic structure of claim 1, further comprising:
a first metal track associated with a backside of the connecting via; and
a second metal track associated with a frontside of the connecting via.

6. The microelectronic structure of claim 1, wherein the backside cell includes a first backside transistor and a second backside transistor, wherein the first backside transistor is located horizontally adjacent to the second backside transistor.

7. The microelectronic structure of claim 6, further comprising:
a plurality of metal tracks associated with the backside cell.

8. The microelectronic structure of claim 7, wherein the plurality of metal tracks includes four metal tracks associated with the backside cell.

9. The microelectronic structure of claim 8, wherein a first group of two metal tracks of the four metal tracks are associated with the first backside transistor and a second group of two metal tracks of the four metal tracks are associated with the second backside transistor.

10. A microelectronic structure comprising:
a stack FET array, wherein the stack FET array includes a plurality of stacked cells, wherein each of the plurality of stacked cells includes a frontside cell and a backside cell, wherein each of the frontside cells includes a first frontside transistor and a second frontside transistor, wherein the first frontside transistor is located horizontally adjacent to the second frontside transistor; and
a connecting via extending from a frontside of the stacked FET array to a backside of the stacked FET array, wherein the connecting via is located at a boundary of the stacked FET array.

11. The microelectronic structure of claim 10, wherein each of the backside cells includes a first backside transistor and a second backside transistor, wherein the first backside transistor is located horizontally adjacent to the second backside transistor.

12. The microelectronic structure of claim 11, wherein the stack FET array includes at least three stacked cells.

13. The microelectronic structure of claim 11, wherein the stack FET array at least four stacked cells.

14. The microelectronic structure of claim 10, further comprising:
a plurality of frontside metal tracks, wherein two frontside metal tracks of the plurality of frontside metal tracks are associated with both the first frontside transistor and the second frontside transistor for each of the plurality of stacked cells.

15. The microelectronic structure of claim 11, further comprising
a plurality of backside metal tracks, wherein two backside metal tracks of the plurality of backside metal tracks are associated with both the first backside transistor and the second backside transistor for each of the plurality of stacked cells.

16. A microelectronic structure comprising:
a first stack FET array, wherein the first stack FET array includes a plurality of first stacked cells, wherein each of the plurality of first stacked cells includes a frontside cell and a backside cell, wherein each of the frontside cells includes a first frontside transistor and a second frontside transistor, wherein the first frontside transistor is located horizontally adjacent to the second frontside transistor;
a second stack FET array, wherein the second stack FET array includes a plurality of second stacked cells, wherein each of the plurality of second stacked cells includes a frontside cell and a backside cell, wherein each of the backside cells includes a first backside transistor and a second backside transistor, wherein the first backside transistor is located horizontally adjacent to the second backside transistor;
a connecting via extending from a frontside of the first stack FET array and a frontside of the second stack FET array to a backside of the first stack FET array and a backside of the second stack FET array, wherein the connecting via is located at an end boundary between the first stack FET array and a beginning boundary of the second stack FET array;
a plurality of frontside metal tracks, wherein two frontside metal tracks of the plurality of frontside metal tracks are associated with each of the frontside transistors; and
a plurality of backside metal tracks, wherein two backside metal tracks of the plurality of backside metal tracks are associated with each of the backside transistors.

17. The microelectronic structure of claim 16, wherein the first stack FET array can include a first number of cells, wherein the first number of cells can be the same, less, or greater than a second number of cells of the second stack FET array.

18. The microelectronic structure of claim 16, further comprising:
a third stack FET array, wherein the third stack FET array includes a plurality of third stacked cells, wherein each of the plurality of the third stacked cells includes a frontside cell and a backside cell, wherein each of the frontside cells includes a first frontside transistor and a second frontside transistor, wherein the first frontside transistor is located horizontally adjacent to the second frontside transistor, wherein each of the backside cells includes a first backside transistor and a second backside transistor, wherein the first backside transistor is located horizontally adjacent to the second backside transistor; and
a second connecting via extending from a frontside of the second stack FET array and a frontside of the third stack FET array to a backside of the of the second stack FET array and a backside of the third stack FET array, wherein the second connecting via is located at an end boundary between the second stack FET array and a beginning boundary of the third stack FET array.

19. The microelectronic structure of claim 18, wherein the third stack FET array can include a third number of cells, wherein the third number of cells can be the same, less, or greater than a first number of cells of the first stack FET array.

20. The microelectronic structure of claim 18, wherein the third stack FET array can include a third number of cells, wherein the third number of cells can be the same, less, or greater than a second number of cells of the second stack FET array.
